(19) United States
(12) Patent Application Publication
(10) Pub. No.: US 2021/0203918 A1
(43) Pub. Date: Jul. 1, 2021

(54) IMAGE SENSING DEVICE, IMAGE SYSTEM INCLUDING IMAGE SENSING DEVICE AND TEST METHOD OF IMAGE SYSTEM

(71) Applicant: SK hynix Inc., Gyeonggi-do (KR)

(72) Inventor: Wanhee JO, Gyeonggi-do (KR)

(21) Appl. No.: 16/896,873

(22) Filed: Jun. 9, 2020

(30) Foreign Application Priority Data
Dec. 30, 2019 (KR) 10-2019-0178125

(51) Int. Cl. H04N 17/00; H04N 5/369; H04N 5/341

(52) U.S. Cl. CPC H04N 17/002; H04N 5/341; H04N 5/3698

(57) ABSTRACT

An image sensing device includes a pixel array coupled to a plurality of row lines and a plurality of column lines, and a row controller suitable for applying a stress voltage to at least one of the plurality of row lines during a stress period based on scan input data having a predetermined pattern.

### CROSS-REFERENCE TO RELATED APPLICATION(S)

This application claims priority under 35 U.S.C. § 119 to Korean Patent Application No. 10-2019-0178125, filed on Dec. 30, 2019, the disclosure of which is incorporated herein by reference in its entirety.

### BACKGROUND

### 1. Field

Various embodiments of the present disclosure relate to a semiconductor design technique, and more particularly, to an image sensing device, an image system including the image sensing device and a test method of the image system.

### 2. Description of the Related Art

Image sensing devices are devices for capturing images using the photosensitive property of semiconductor. Image sensing devices may be roughly classified into charge-coupled device (CCD) image sensing devices and complementary metal-oxide semiconductor (CMOS) image sensing devices. Recently, CMOS image sensing devices are widely used because the CMOS image sensing devices can allow both analog and digital control circuits to be directly implemented on a single integrated circuit (IC).

### SUMMARY

Various embodiments of the present disclosure are directed to an image sensing device that can prevent a defect of a pixel array while detecting a defect of a row decoder, an image system including the image sensing device and a test method of the image system.

In accordance with an embodiment, an image sensing device may include: a pixel array coupled to a plurality of row lines and a plurality of column lines; and a row controller suitable for applying a stress voltage to at least one of the plurality of row lines during a stress period based on scan input data having a predetermined pattern.

In accordance with an embodiment, an image system may include: a test device suitable for generating scan input data having a predetermined pattern in a test mode; and an image sensing device including a row controller and a pixel array coupled to each other through a plurality of row lines, and suitable for generating scan output data, indicating whether the row controller has a defect through a scan test operation, and applying a stress voltage to at least one of the plurality of row lines, based on the scan input data in the test mode.

In accordance with an embodiment, a test method of an image system may include: outputting, by a test device, scan input data to an image sensing device during a stress period; applying, by the image sensing device, a stress voltage to at least one of a plurality of row lines, coupled between a row controller and a pixel array, based on the scan input data during the stress period; and outputting, by the image sensing device, scan output data, indicating whether the row controller has a defect, to the test device through the scan test operation during a defect detection period after the stress period.

These and other features and advantages of the present disclosure will become apparent to those skilled in the art of the invention from the following detailed description in conjunction with the following drawings.

### BRIEF DESCRIPTION OF THE DRAWINGS

FIG. 1 is a block diagram illustrating an image system in accordance with various embodiments of the present invention.

FIG. 2 is a block diagram illustrating an image sensing device illustrated in FIG. 1 in accordance with various embodiments of the present invention.

FIG. 3 is a circuit diagram of a unit pixel circuit employed in FIG. 2 in accordance with various embodiments of the present invention.

FIG. 4 is a diagram illustrating a layout of conductive lines coupled to the unit pixel circuit illustrated in FIG. 3 in accordance with various embodiments of the present invention.

FIG. 5 is a block diagram illustrating a row controller illustrated in FIG. 2 in accordance with various embodiments of the present invention.

FIG. 6 is a block diagram illustrating a scan chain and a driver illustrated in FIG. 5 in accordance with various embodiments of the present invention.

FIG. 7 is a block diagram illustrating an input cell illustrated in FIG. 6 in accordance with various embodiments of the present invention.

FIG. 8 is a block diagram illustrating a first scan cell group illustrated in FIG. 6 in accordance with various embodiments of the present invention.

FIG. 9 is a block diagram illustrating an n^{th} scan cell group illustrated in FIG. 6 in accordance with various embodiments of the present invention.

FIG. 10 is a timing diagram illustrating a test method of the image system illustrated in FIG. 1 in accordance with various embodiments of the present invention.

### DETAILED DESCRIPTION

Various embodiments are described below in more detail with reference to the accompanying drawings. These embodiments are provided so that this disclosure is thorough and complete, and fully conveys the scope of the present disclosure to those skilled in the art.

It will be understood that when an element is referred to as being “connected to”, or “coupled to” another element, it may be directly on, connected to, or coupled to the other element, or one or more intervening elements may be present. In addition, it will also be understood that the terms “comprises,” “comprising,” “includes,” and “including” when used in this specification, specify the presence of the stated elements and do not preclude the presence or addition of one or more other elements. As used herein, singular forms may include the plural forms as well, and vice versa, unless the context clearly indicates otherwise. The articles “a” and “an” as used in this application and the appended claims should generally be construed to mean “one or more” unless specified otherwise or it is clear from context to be directed to a singular form.

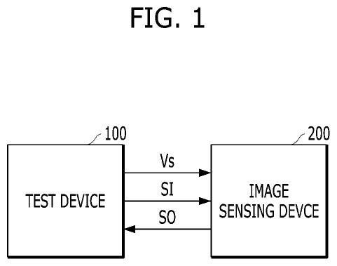

FIG. 1 is a block diagram illustrating an image system in accordance with various embodiments of the present invention.

Referring to FIG. 1, the image system may include a test device 100 and an image sensing device 200.

The test device 100 may control a scan test operation and a stress application operation of the image sensing device 200 in a test mode. For example, the test device 100 may generate scan input data SI required for the scan test operation and the stress application operation, and output the scan input data SI to the image sensing device 200, during a stress period. The scan input data SI may include a plurality of data values having a predetermined pattern. For example, the plurality of data values of the scan input data SI may have a pattern in which “1” and “0” alternate. Hereinafter, a pattern of “1010 . . . 10” is referred to as a first pattern, and a pattern of “0101 . . . 01” is referred to as a second pattern.

The test device 100 may detect a defect of the image sensing device 200 in the test mode. For example, the test device 100 may detect the defect of the image sensing device 200 by comparing scan output data SO, provided from the image sensing device 200, with previously-stored reference data during a defect detection period. The defect may include a defect of a row controller 220 included in the image sensing device 200. The defect may be a defect of a row decoder 221 included in the row controller 220.

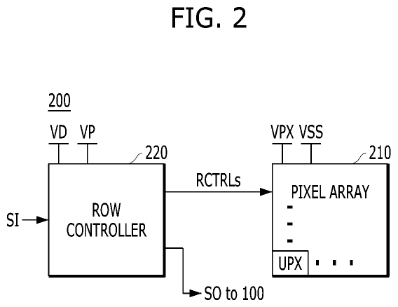

The test device 100 may supply a plurality of voltages Vs to the image sensing device 200 in the test mode. The plurality of voltages Vs may include first to fourth voltages VPX, VSS, VD and VP related to a power source (refer to FIG. 2). Particularly, the test device 100 may supply a stress voltage, required for the stress application operation, to the image sensing device 200 in lieu of at least one of the plurality of voltages Vs during the stress period. For example, the test device 100 may supply the fourth voltage VP having a voltage level which corresponds to the stress voltage, to the image sensing device 200 during the stress period, and supply the first voltage VPX having the voltage level which corresponds to the stress voltage, and the second voltage VSS having a ground voltage level to the image sensing device 200 during the stress period, or supply the first voltage VPX having the ground voltage level and the second voltage VSS having the voltage level which corresponds to the stress voltage, to the image sensing device 200 during the stress period.

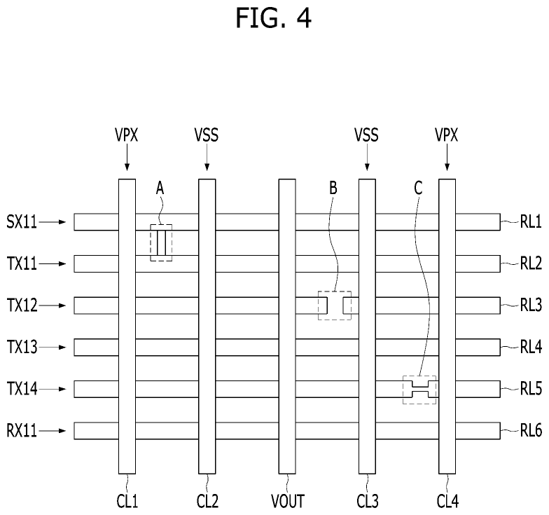

The image sensing device 200 may receive the scan input data SI in the test mode. Based on the scan input data SI, the image sensing device 200 may apply the stress voltage to a stress application target through the stress application operation during the stress period, and generate the scan output data SO through the scan test operation during the defect detection period. The stress application target may include a plurality of row lines RL1 to RL6 and a plurality of power source lines CL1 to CL4, as described below (refer to FIG. 4).

FIG. 2 is a block diagram illustrating a simplified configuration of the image sensing device 200 illustrated in FIG. 1. FIG. 2 illustrates only those components relating to the subject matter of the present disclosure.

Referring to FIG. 2, the image sensing device 200 may include a pixel array 210 and the row controller 220.

The pixel array 210 may include a plurality of unit pixel circuits UPX disposed at intersections of a plurality of rows and a plurality of columns. Each of the unit pixel circuits UPX may include a single pixel or a plurality of pixels. Hereinafter, it is described as an example that the unit pixel circuit UPX includes the plurality of pixels. For example, the unit pixel circuit UPX may include four pixels arranged in a 2×2 matrix. The unit pixel circuit UPX may be coupled to the row lines RL1 to RL6 and a plurality of column lines CL1 to CL4 and VOUT (refer to FIG. 4).

The pixel array 210 may generate pixel signals for each row based on row control signals RCTRLs allocated for each row in a normal mode. The unit pixel circuit UPX uses the first voltage VPX having a high voltage level and the second voltage VSS having a low voltage level in the normal mode.

The row controller 220 may selectively apply the stress voltage to the row lines RL1 to RL6 based on the scan input data SI in the test mode. For example, the row controller 220 may apply the stress voltage to the odd-numbered row lines RL1, RL3 and RL5 or the even-numbered row lines RL2, RL4 and RL6, among the row lines RL1 to RL6, according to the first pattern or the second pattern of the scan input data SI during the stress period. The row controller 220 may use the third and fourth voltages VD and VP. Particularly, the fourth voltage VP may have a level, which is higher in the test mode than in the normal mode, and the row controller 220 may use the fourth voltage VP as the stress voltage in the test mode.

The row controller 220 may perform the scan test operation based on the scan input data SI in the test mode. For example, the row controller 220 may perform a logic operation on a plurality of data values, included in the scan input data SI, in a predetermined manner during a loading period, to generate the scan output data SO, and output the scan output data SO to the test device 100 during the defect detection period.

The row controller 220 may selectively drive the row lines RL1 to RL6 based on the fourth voltage VP having a lower voltage level than the stress voltage in the normal mode to generate the row control signals RCTRLs.

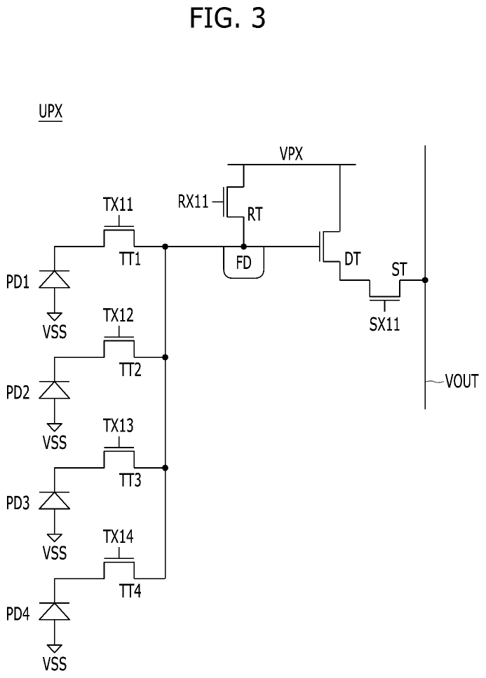

FIG. 3 is a circuit diagram illustrating the unit pixel circuit UPX illustrated in FIG. 2.

Referring to FIG. 3, the unit pixel circuit UPX may include four light elements PD1, PD2, PD3 and PD4. The four light elements PD1, PD2, PD3 and PD4 may share one floating diffusion node FD. The unit pixel circuit UPX may include the first to fourth light elements PD1, PD2, PD3 and PD4, first to fourth transmission elements TT1, TT2, TT3 and TT4, the floating diffusion node FD, a reset element RT, a driving element DT and a selection element ST.

The first light element PD1 may be coupled between the first transmission element TT1 and a supply terminal of the second voltage VSS. The first light element PD1 may generate a light charge corresponding to incident light in the normal mode, and transmit the light charge to the floating diffusion node FD for a first transmission time. For example, the first light element PD1 may include a photo diode.

The second light element PD2 may be coupled between the second transmission element TT2 and the supply terminal of the second voltage VSS. The second light element PD2 may generate a light charge corresponding to incident light in the normal mode, and transmit the light charge to the floating diffusion node FD for a second transmission time. For example, the second light element PD2 may include a photo diode.

The third light element PD3 may be coupled between the third transmission element TT3 and the supply terminal of the second voltage VSS. The third light element PD3 may generate a light charge corresponding to incident light in the normal mode, and transmit the light charge to the floating diffusion node FD for a third transmission time. For example, the third light element PD3 may include a photo diode.

The fourth light element PD4 may be coupled between the fourth transmission element TT4 and the supply terminal of the second voltage VSS. The fourth light element PD4 may generate a light charge corresponding to incident light in the normal mode, and transmit the light charge to the floating diffusion node FD for a fourth transmission time. For example, the fourth light element PD4 may include a photo diode.

The first transmission element TT1 may be provided between the first light element PD1 and the floating diffusion node FD. The first transmission element TT1 may transmit the light charge, generated from the first light element PD1, to the floating diffusion node FD for the first transmission time, based on a first transmission control signal TX11 of the row control signals RCTRLs. For example, the first transmission element TT1 may include an NMOS transistor having a gate to which the first transmission control signal TX11 is inputted, and a source and a drain coupled between the floating diffusion node FD and the first light element PD1.

The second transmission element TT2 may be provided between the second light element PD2 and the floating diffusion node FD. The second transmission element TT2 may transmit the light charge, generated from the second light element PD2, to the floating diffusion node FD for the second transmission time, based on a second transmission control signal TX12 of the row control signals RCTRLs. For example, the second transmission element TT2 may include an NMOS transistor having a gate to which the second transmission control signal TX12 is inputted, and a source and a drain coupled between the floating diffusion node FD and the second light element PD2.

The third transmission element TT3 may be provided between the third light element PD3 and the floating diffusion node FD. The third transmission element TT3 may transmit the light charge, generated from the third light element PD3, to the floating diffusion node FD for the third transmission time, based on a third transmission control signal TX13 of the row control signals RCTRLs. For example, the third transmission element TT3 may include an NMOS transistor having a gate to which the third transmission control signal TX13 is inputted, and a source and a drain coupled between the floating diffusion node FD and the third light element PD3.

The fourth transmission element TT4 may be provided between the fourth light element PD4 and the floating diffusion node FD. The fourth transmission element TT4 may transmit the light charge, generated from the fourth light element PD4, to the floating diffusion node FD for the fourth transmission time, based on a fourth transmission control signal TX14 of the row control signals RCTRLs. For example, the fourth transmission element TT4 may include an NMOS transistor having a gate to which the fourth transmission control signal TX14 is inputted, and a source and a drain coupled between the floating diffusion node FD and the fourth light element PD4.

The floating diffusion node FD may sequentially accumulate the light charge generated from the first light element PD1, the light charge generated from the second light element PD2, the light charge generated from the third light element PD3 and the light charge generated from the fourth light element PD4. For example, a junction capacitor (not illustrated) may be coupled to the floating diffusion node FD, and the light charges may be accumulated in the junction capacitor.

The reset element RT may initialize the floating diffusion node FD based on a reset control signal RX11 of the row control signals RCTRLs. For example, the reset element RT may initialize the floating diffusion node FD for a first reset time just before the first transmission time, initialize the floating diffusion node FD for a second reset time just before the second transmission time, initialize the floating diffusion node FD for a third reset time just before the third transmission time, and initialize the floating diffusion node FD for a fourth reset time just before the fourth transmission time. For example, the reset element RT may include an NMOS transistor having a gate to which the reset control signal RX11 is inputted, and a drain and a source coupled between a supply terminal of the first voltage VPX and the floating diffusion node FD.

The driving element DT may drive a pixel signal with the first voltage VPX based on a voltage loaded on the floating diffusion node FD. For example, the driving element DT may generate the pixel signal corresponding to the light charge of the first light element PD1 for the first transmission time, generate the pixel signal corresponding to the light charge of the second light element PD2 for the second transmission time, generate the pixel signal corresponding to the light charge of the third light element PD3 for the third transmission time, and generate the pixel signal corresponding to the light charge of the fourth light element PD4 for the fourth transmission time. For example, the driving element DT may include an NMOS transistor having a gate coupled to the floating diffusion node FD, and a drain and a source coupled between the supply terminal of the first voltage VPX and the selection element ST.

The selection element ST may transmit the pixel signal to an output line VOUT based on a selection control signal SX11 of the row control signals RCTRLs. For example, the selection element ST may include an NMOS transistor having a gate to which the selection control signal SX11 is inputted and a drain and a source coupled between the driving element DT and the output line VOUT.

FIG. 4 is a diagram illustrating a layout of conductive lines coupled to the unit pixel circuit UPX illustrated in FIG. 3.

Referring to FIG. 4, the conductive lines may include the plurality of row lines RL1 to RL6 and the plurality of column lines CL1 to CL4 and VOUT. The row lines RL1 to RL6 and the column lines CL1 to CL4 and VOUT may be disposed on different metal layers. For example, the metal layer on which the column lines CL1 to CL4 and VOUT are disposed may be formed at a higher level than the metal layer on which the row lines RL1 to RL6 are disposed.

The row lines RL1 to RL6 may include first to sixth row control lines RL1 to RL6 extended in parallel in a row direction of the pixel array 210. The first row control line RL1 may be a line to which the selection control signal SX11 is applied. The second row control line RL2 may be a line to which the first transmission control signal TX11 is applied. The third row control line RL3 may be a line to which the second transmission control signal TX12 is applied. The fourth row control line RL4 may be a line to which the third transmission control signal TX13 is applied. The fifth row control line RL5 may be a line to which the fourth transmission control signal TX14 is applied. The sixth row control line RL6 may be a line to which the reset control signal RX11 is applied. Although it is described in the present embodiment that the first to sixth row control lines RL1 to RL6 are arranged sequentially from one side to the other, the present disclosure is not limited thereto, and the order of arrangement may be changed according to a design.

There may be defects in the first to sixth row control lines RL1 to RL6. The defects may include a micro bridge defect A occurring between at least two of the first to sixth row control lines RL1 to RL6, an open defect B occurring in at least one of the first to sixth row control lines RL1 to RL6, and a weak line defect C occurring in at least one of the first to sixth row control lines RL1 to RL6. For example, in the illustrated embodiment of FIG. 4, a micro bridge defect A is shown occurring between first and second row control lines RL1 and RL2, an open defect B is shown occurring in the third row control line RL3, and a weak line defect C is shown occurring in the fifth row control line RL5. The defects A, B and C may be progressive defects or potential defects. The defects A, B and C may be removed by applying the stress voltage to at least one of the first to sixth row control lines RL1 to RL6. A principle in which the defects A, B and C are removed may be similar to a principle in which a fuse is ruptured or programmed.

The column lines CL1 to CL4 and VOUT may include the output line VOUT and the first to fourth power source lines CL1 to CL4, which are extended in parallel in a column direction of the pixel array 210. The output line VOUT may output the pixel signal. The first power source line CL1 may be supplied with the first voltage VPX. The second power source line CL2 may be supplied with the second voltage VSS. The third power source line CL3 may be supplied with the second voltage VSS. The fourth power source line CL4 may be supplied with the first voltage VPX. In the embodiment of FIG. 4, four power lines, i.e., the first to fourth power lines CL1 to CL4 are arranged symmetrically on either side of the output line VOUT.

Specifically, the first and second power source lines CL1 and CL2 are positioned on one side of the output line while the third and fourth power source lines CL3 and CL4 are arranged symmetrically to the first and second power lines, respectively, on the other side of the output line VOUT. However, the present disclosure is not limited thereto, and the number and arrangement of the power lines may be changed according to a design.

Although not illustrated, there may be the defects A, B and C in the first to fourth power source lines CL1 to CL4. The defects A, B and C may be removed by applying the stress voltage to at least one of the first to fourth power source lines CL1 to CL4.

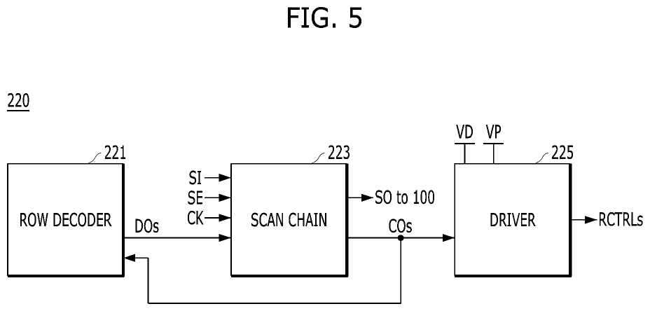

FIG. 5 is a block diagram illustrating a configuration for the row controller 220 of FIG. 2 according to an embodiment.

Referring to FIG. 5, the row controller 220 may include the row decoder 221, a scan chain 223 and a driver 225.

The row decoder 221 may generate a plurality of logic signals DOs corresponding to a plurality of scan signals COs in the test mode. For example, the row decoder 221 may perform a logic operation on the plurality of scan signals COs received from the scan chain 223 in a predetermined manner during at least one period of the stress period and the loading period, thereby generating the plurality of logic signals DOs indicating whether the row decoder 221 has a defect. When the row decoder 221 is in a normal state where there is no defect, the logic signals DOs may include pass values which are expected values which correspond to the scan signals COs. On the other hand, when the row decoder 221 is in an abnormal state where there is a defect, the logic signals DOs may include fail values i.e., values which do not correspond to expected values based on the scan signals COs.

The row decoder 221 may generate the logic signals DOs corresponding to the row control signals RCTRLs under the control of a timing controller (not illustrated) in the normal mode.

The scan chain 223 may generate the scan signals COs based on the scan input data SI, a period division signal SE, a clock signal CK and the logic signals DOs in the test mode. The period division signal SE and the clock signal CK may be provided from the test device 100 or generated by the image sensing device 200. For example, the scan chain 223 may generate the scan signals COs corresponding to the first pattern or the second pattern of the scan input data SI during the stress period, load the logic signals DOs during the loading period, and sequentially output the loaded logic signals Dos, as the scan output data SO, to the test device 100 during the defect detection period.

The scan chain 223 may generate the scan signals COs corresponding to the row control signals RCTRLs based on the logic signals DOs in the normal mode.

The driver 225 may selectively apply the stress voltage in lieu of the row control signals RCTRLs, based on the scan signals COs in the test mode. For example, the driver 225 may selectively drive the row lines RL1 to RL6 with the fourth voltage VP corresponding to the stress voltage during the stress period.

The driver 225 may generate the row control signals RCTRLs corresponding to the logic signals DOs based on the scan signals COs in the normal mode.

The driver 225 may receive the scan signals COs by using the third voltage VD, and output the row control signals RCTRLs by using the fourth voltage VP. Although not illustrated, at least one of the scan chain 223 and the row decoder 221 may also use the third voltage VD. For example, the scan chain 223 may output the scan signals COs by using the third voltage VD.

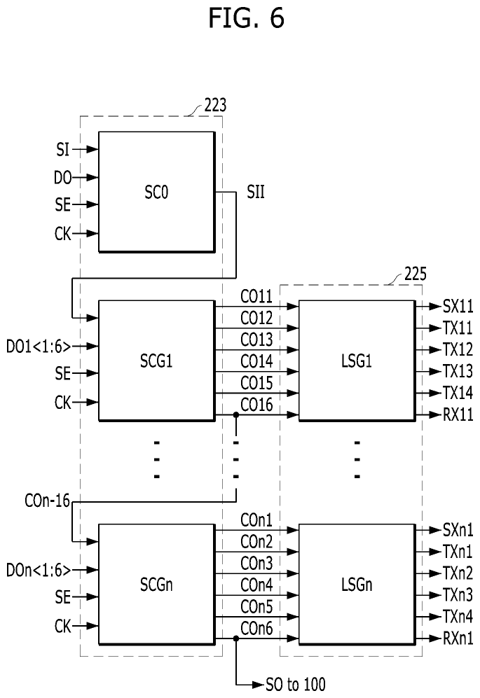

FIG. 6 is a block diagram illustrating the scan chain 223 and the driver 225 illustrated in FIG. 5.

Referring to FIG. 6, the scan chain 223 may include an input cell SC0 and first to n^{th} scan cell groups SCG1 to SCGn.

The input cell SC0 may generate scan data SII based on the scan input data SI, the logic signal DO, the period division signal SE and the clock signal CK in the test mode. The logic signal DO may be any one of the plurality of logic signals DOs. For example, the input cell SC0 may sequentially receive the scan input data SI, and generate the scan data SII corresponding to the scan input data SI, during the stress period.

The first to n^{th} scan cell groups SCG1 to SCGn may have the same structure except for signals SII, . . . , and Con−16 from previous cells and logic signals DO1<1:6>, . . . , and DOn<1:6> inputted thereto. For example, the first scan cell group SCG1 may generate first scan signals CO11 to CO16 corresponding to first row control signals SX11, RX11 and TX11 to TX14 based on the scan data SII outputted from the input cell SC0, the first logic signals DO1<1:6> of the logic signals DOs, the period division signal SE, and the clock signal CK. The first row control signals SX11, RX11 and TX11 to TX14 may be some of the row control signals RCTRLs, and the first scan signals CO11 to CO16 may be some of the scan signals COs. The n^{th} scan cell group SCGn may generate n^{th} scan signals COn1 to COn6 corresponding to n^{th} row control signals SXn1, RXn1 and TXn1 to TXn4 based on the scan data COn−16 outputted from the (n−1)^{th} scan cell group SCGn−1, the n^{th} logic signals DOn<1:6> of the logic signals DOs, the period division signal SE and the clock signal CK. The n^{th} row control signals SXn1, RXn1 and TXn1 to TXn4 may be some of the row control signals RCTRLs, and the n^{th} scan signals COn1 to COn6 may be some of the scan signals COs.

The first to n^{th} scan cell groups SCG1 to SCGn may sequentially shift the scan data SII outputted from the input cell SC0, and generate the scan signals COs, during the stress period. The first to n^{th} scan cell groups SCG1 to SCGn may load the logic signals DOs during the loading period, and output the loaded logic signals DOs as the scan output data SO during the defect detection period.

The driver 225 may include first to n^{th} level shifter groups LSG1 to LSGn. Each of the first to n^{th} level shifter groups LSG1 to LSGn may include first to sixth level shifters. The first to sixth level shifters may be coupled, in one-to-one correspondence, to the first to sixth row control lines RL1 to RL6 coupled to each row of the pixel array 210. Each of the first to sixth level shifters may receive the respective scan signals by using the third voltage VD, and output the respective row control signals by using the fourth voltage VP.

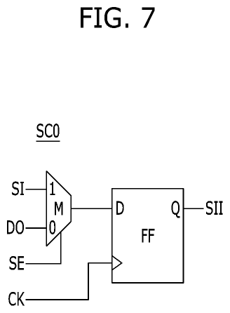

FIG. 7 is a block diagram illustrating the input cell SC0 illustrated in FIG. 6.

Referring to FIG. 7, the input cell SC0 may include a multiplexer M and a flipflop FF.

The multiplexer M may select and output any one of the scan input data SI and the logic signal DO based on the period division signal SE.

The flipflop FF may sequentially output an output signal of the multiplexer M as the scan data SII based on the clock signal CK.

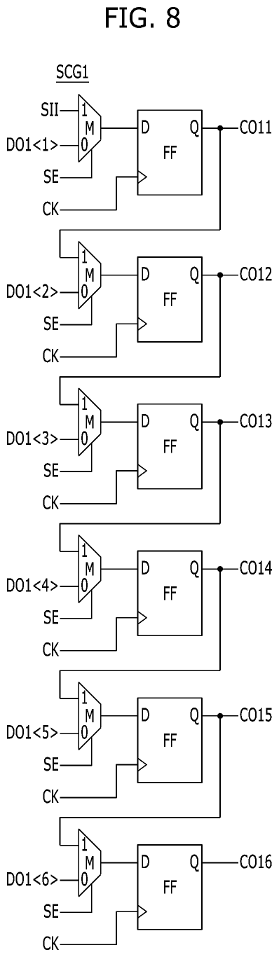

FIG. 8 is a block diagram illustrating the first scan cell group SCG1 illustrated in FIG. 6.

Referring to FIG. 8, the first scan cell group SCG1 may include first to sixth scan cells. The first to sixth scan cells may be coupled, in one-to-one correspondence, to the first to sixth row control lines RL1 to RL6 coupled to a first row of the pixel array 210. The first scan cell may output the first scan signal CO11 based on the scan data SII, the first logic signal DO1<1>, the period division signal SE and the clock signal CK. The second scan cell may output the first scan signal CO12 based on the first scan signal CO11 outputted from the first scan cell, the first logic signal DO1<2>, the period division signal SE and the clock signal CK. The third scan cell may output the first scan signal CO13 based on the first scan signal CO12 outputted from the second scan cell, the first logic signal DO1<3>, the period division signal SE and the clock signal CK. The fourth scan cell may output the first scan signal CO14 based on the first scan signal CO13 outputted from the third scan cell, the first logic signal DO1<4>, the period division signal SE and the clock signal CK. The fifth scan cell may output the first scan signal CO15 based on the first scan signal CO14 outputted from the fourth scan cell, the first logic signal DO1<5>, the period division signal SE and the clock signal CK. The sixth scan cell may output the first scan signal CO16 based on the first scan signal CO15 outputted from the fifth scan cell, the first logic signal DO1<6>, the period division signal SE and the clock signal CK.

Each of the first to sixth scan cells may include a multiplexer M and a flipflop FF. Since each of the first to sixth scan cells may have the same configuration as the input cell SC0 illustrated in FIG. 7, detailed descriptions thereof are omitted.

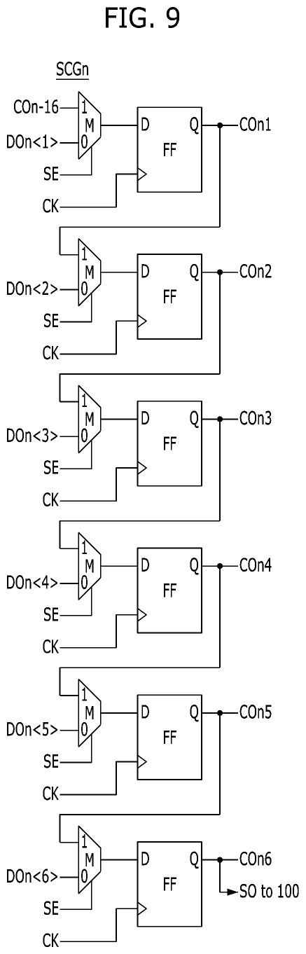

FIG. 9 is a block diagram illustrating a configuration of the n^{th} scan cell SCGn of FIG. 6 according to an embodiment.

Referring to FIG. 9, the n^{th} scan cell SCGn may include first to sixth scan cells. The first to sixth scan cells may be coupled, in one-to-one correspondence, to the first to sixth row control lines RL1 to RL6 coupled to an n^{th} row of the pixel array 210. The first scan cell may output the n^{th} scan signal COn1 based on the (n−1)^{th} scan signal COn−16, the n^{th} logic signal DOn<1>, the period division signal SE and the clock signal CK. The second scan cell may output the n^{th} scan signal COn2 based on the n^{th} scan signal COn1 outputted from the first scan cell, the n^{th} logic signal DOn<2>, the period division signal SE and the clock signal CK. The third scan cell may output the n^{th} scan signal COn3 based on the n^{th} scan signal COn2 outputted from the second scan cell, the n^{th} logic signal DOn<3>, the period division signal SE and the clock signal CK. The fourth scan cell may output the n^{th} scan signal COn4 based on the n^{th} scan signal COn3 outputted from the third scan cell, the n^{th} logic signal DOn<4>, the period division signal SE and the clock signal CK. The fifth scan cell may output the n^{th} scan signal COn5 based on the n^{th} scan signal COn4 outputted from the fourth scan cell, the n^{th} logic signal DOn<5>, the period division signal SE and the clock signal CK. The sixth scan cell may output the n^{th} scan signal COn6 based on the n^{th} scan signal COn5 outputted from the fifth scan cell, the n^{th} logic signal DOn<6>, the period division signal SE and the clock signal CK. The scan output data SO may be sequentially outputted through an output terminal of the n^{th} scan signal COn6.

Each of the first to sixth scan cells may include a multiplexer M and a flipflop FF. Since each of the first to sixth scan cells may have the same configuration as the input cell SC0 illustrated in FIG. 7, detailed descriptions thereof are omitted.

Hereinafter, a test method of the image system having the above-described configuration in accordance with an embodiment is described.

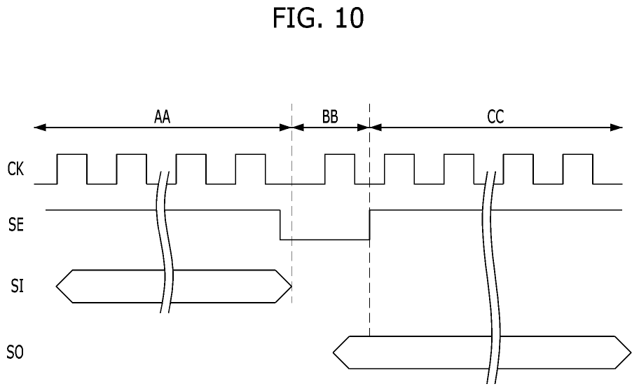

FIG. 10 is a timing diagram illustrating the test method of the image system illustrated in FIG. 1.

Referring to FIG. 10, the test device 100 may output the scan image data SI to the image sensing device 200 during the stress period AA. The test device 100 may supply the fourth voltage VP having a voltage level, which corresponds to the stress voltage, to the image sensing device 200 during the stress period AA, and supply the first voltage VPX having the voltage level, which corresponds to the stress voltage, and the second voltage VSS having the ground voltage level to the image sensing device 200 during the stress period AA, or supply the first voltage VPX having the ground voltage level and the second voltage VSS having the voltage level, which corresponds to the stress voltage, to the image sensing device 200 during the stress period AA.

The image sensing device 200 may apply the stress voltage to half of the first to sixth row control lines RL1 to RL6 and may apply the ground voltage to a remaining half of the first to sixth row control lines RL1 to RL6, based on the scan input data SI during the stress period AA. The half lines to which the stress voltage is applied may be determined according to the first pattern or the second pattern of the scan input data SI. For example, the image sensing device 200 may apply the stress voltage to the odd-numbered row control lines RL1, RL3 and RL5 and may apply the ground voltage to the even-numbered row control lines RL2, RL4 and RL6, among the first to sixth row control lines RL1 to RL6 according to the first pattern of the scan input data SI. Alternatively, the image sensing device 200 may apply the stress voltage to the even-numbered row control lines RL2, RL4 and RL6 and may apply the ground voltage to the odd-numbered row control lines RL1, RL3 and RL5, among the first to sixth row control lines RL1 to RL6 according to the second pattern of the scan input data SI. In addition, according to the voltage levels of the first and second voltages VPX and VSS supplied from the test device 100, the stress voltage may be applied to the first and fourth column control lines CL1 and CL4 of the first to fourth column control lines CL1 to CL4 of the image sensing device 200, and the ground voltage may be applied to the second and third column control lines CL2 and CL3. Alternatively, according to the voltage levels of the first and second voltages VPX and VSS supplied from the test device 100, the stress voltage may be applied to the second and third column control lines CL2 and CL3 of the first to fourth column control lines CL1 to CL4 of the image sensing device 200, and the ground voltage may be applied to the first and fourth column control lines CL1 and CL4. This is summarized according to the number of cases as shown in Table 1 below.

TABLE 1

| | CL1 & | CL2 & | | | | | | |
|---|---|---|---|---|---|---|---|---|
| No. | CL4 | CL3 | RL1 | RL2 | RL3 | RL4 | RL5 | RL6 |
| 1 | 1 | 0 | 1 | 0 | 1 | 0 | 1 | 0 |
| 2 | 0 | 1 | 0 | 1 | 0 | 1 | 0 | 1 |
| 3 | 0 | 1 | 1 | 0 | 1 | 0 | 1 | 0 |
| 4 | 1 | 0 | 0 | 1 | 0 | 1 | 0 | 1 |

As shown in Table 1 above, “1” may indicate that the stress voltage is applied, and “0” may indicate that the ground voltage is applied.

Accordingly, the defects A, B and C that may occur in the first to sixth row control lines RL1 to RL6, and the defects A, B and C that may occur in the first to fourth column control lines CL to CL4 may be removed based on voltage differences between adjacent lines.

The image sensing device 200 may perform a logic operation on a plurality of data values, included in the scan input data SI, in a predetermined manner during the loading period BB, thereby loading the scan output data SO indicating whether the image sensing device 200 has a defect. More specifically, the scan output data SO may indicate a defect of the row decoder 221 included in the image sensing device 200.

The image sensing device 200 may output the scan output data SO to the test device 100 through the scan test operation during the defect detection period CC. The test device 100 may compare the scan output data SO with the previously-stored reference data during the defect detection period CC, thereby determining whether the row decoder 221 has a defect.

The stress period AA, the loading period BB, and the defect detection period CC may be repeated at least once. When the periods AA, BB, and CC are repeated, a pattern of the data values included in the scan input data SI may be changed. For example, the pattern may be changed from the first pattern to the second pattern or from the second pattern to the first pattern (refer to Table 1 above).

According to the embodiment of the present disclosure, a defect of the row decoder may be easily detected, and a defect of the pixel array may be prevented. Consequently, the image sensing device may have excellent quality competitiveness.

While the present disclosure has been illustrated and described with respect to specific embodiments, the disclosed embodiments are not intended to be restrictive. Further, it is noted that the present disclosure may be achieved in various ways through substitution, change, and modification, as those skilled in the art will recognize in light of the present disclosure, without departing from the spirit and/or scope of the present disclosure. The present disclosure is intended to embrace all such substitutions, changes and modifications that fall within the scope of the following claims.

1. An image sensing device comprising:
a pixel array coupled to a plurality of row lines and a plurality of column lines; and
a row controller configured to alternately apply a stress voltage and a voltage to the plurality of row lines during a stress period based on scan input data having a predetermined pattern,
wherein the stress voltage and the voltage have different voltage levels.

2. The image sensing device of claim 1, wherein the row controller uses a predetermined voltage to selectively drive the plurality of row lines in a normal mode, and
wherein the stress voltage has a higher level than the predetermined voltage.

3. The image sensing device of claim 1, wherein the at least one row line to which the stress voltage is applied is determined according to the predetermined pattern of the scan input data.

4. The image sensing device of claim 1, wherein the plurality of column lines include a plurality of power source lines, and
wherein the stress voltage is applied to at least one of the power source lines during the stress period.

5. The image sensing device of claim 1, wherein the row controller generates scan output data, and outputs the scan output data to a test device during a defect detection period by performing a logic operation on a plurality of data values, included in the scan input data, in a predetermined manner during a loading period, based on the scan input data.

6. The image sensing device of claim 1, wherein the row controller includes:
a scan chain configured to generate a plurality of scan signals corresponding to the predetermined pattern of the scan input data during the stress period, based on the scan input data, a period division signal, and a clock signal; and
a driver configured to drive the at least one of the plurality of row lines with the stress voltage during the stress period, based on the scan signals.

7. The image sensing device of claim 6, wherein the scan chain includes:
an input cell configured to sequentially receive the scan input data during the stress period, based on the period division signal and the clock signal; and
a plurality of scan cells configured to be coupled to the plurality of row lines, in one-to-one correspondence, and configured to sequentially shift the scan input data outputted from the input cell and generate the plurality of scan signals during the stress period, based on the period division signal and the clock signal.

8. The image sensing device of claim 6, wherein the driver includes a plurality of level shifters, coupled to the plurality of row lines in one-to-one correspondence.

9. The image sensing device of claim 6, wherein the row controller further includes a row decoder for generating a plurality of logic signals indicating whether the row decoder has a defect, by performing a logic operation on the plurality of scan signals in a predetermined manner during the stress period, and the scan chain sequentially outputs scan output data, corresponding to the plurality of logic signals, to a test device during the defect detection period after the stress period, based on the period division signal and the clock signal.

10. An image system comprising:
a test device configured to generate scan input data having a predetermined pattern in a test mode; and
an image sensing device including a row controller and a pixel array coupled to each other through a plurality of row lines, and configured to generate scan output data, indicating whether the row controller has a defect through a scan test operation, and alternately apply a stress voltage and a voltage to the plurality of row lines, based on the scan input data in the test mode,
wherein the stress voltage and the voltage have different voltage levels.

11. The image system of claim 10, wherein the test device determines whether the row controller has a defect, by comparing the scan output data with previously-stored reference data.

12. The image system of claim 10, wherein the stress voltage has a higher level than a voltage, which is used by the row controller in a normal mode.

13. The image system of claim 10, wherein the at least one row line to which the stress voltage is applied is determined according to the predetermined pattern of the scan input data.

14. The image system of claim 10, wherein the test device applies the stress voltage to at least one of a plurality of power source lines, coupled to the pixel array, in the test mode.

15. A test method of an image system, comprising:
outputting, by a test device, scan input data having a predetermined pattern to an image sensing device during a stress period;
alternately applying, by the image sensing device, a stress voltage and a voltage to a plurality of row lines, coupled between a row controller and a pixel array, based on the scan input data during the stress period, wherein the stress voltage and the voltage have different voltage levels; and
outputting, by the image sensing device, scan output data, indicating whether the row controller has a defect, to the test device through the scan test operation during a defect detection period after the stress period.

16. The test method of claim 15, wherein the test device determines whether the row controller has a defect, by comparing the scan output data with previously-stored reference data, during the defect detection period.

17. The test method of claim 15, wherein the test device applies the stress voltage to at least one of a plurality of power source lines, coupled to the pixel array, during the stress period, and
wherein the stress voltage is used in a test mode, and has a higher level than a voltage which is used by the row controller in a normal mode.

18. The test method of claim 15, wherein the scan input data has a predetermined pattern, and includes a plurality of data values inputted in series, and
wherein the at least one row line to which the stress voltage is applied is determined according to the predetermined pattern of the scan input data.

19. The test method of claim 15, wherein during a loading period between the stress period and the defect detection period, the row controller generates the scan output data by performing a logic operation on the plurality of data values, included in the scan input data, in a predetermined manner.

20. The test method of claim 15, wherein the stress period and the defect detection period are repeated at least once, and
wherein when the stress period and the defect detection period are repeated, a pattern of the plurality of data values included in the scan input data is changed.
